(19) United States
(12) Patent Application Publication
(10) Pub. No.: US 2023/0030472 A1
(43) Pub. Date: Feb. 2, 2023

(54) OPTICAL SENSOR

(71) Applicants: STMicroelectronics (Crolles 2) SAS, Crolles (FR); STMicroelectronics (Grenoble 2) SAS, Grenoble (FR)

(72) Inventors: Axel CROCHERIE, Grenoble (FR); Olivier LE-BRIZ, Saint-Gervais (FR)

(73) Assignees: STMicroelectronics (Crolles 2) SAS, Crolles (FR); STMicroelectronics (Grenoble 2) SAS, Grenoble (FR)

(21) Appl. No.: 17/869,172

(22) Filed: Jul. 20, 2022

(30) Foreign Application Priority Data
Jul. 27, 2021 (FR) 2108146

(51) Int. Cl. H01L 27/146

(52) U.S. Cl. CPC H01L 27/14627; H01L 27/14605; G02B 13/22

(57) ABSTRACT

An optical sensor includes pixels, with each pixel formed by a photodetector and a telecentric system topping the photodetector. Each telecentric system includes: an opaque layer with openings facing the photodetector and a microlens facing each opening and arranged between the opaque layer and the photodetector. Each pixel further includes an optical filter between the microlenses and the photodetector. The optical filter may, for example, be an interference filter, a diffraction grating-based filter or a metasurface-based filter.

### PRIORITY CLAIM

This application claims the priority benefit of French Application for Patent No. 2108146, filed on Jul. 27, 2021, the content of which is hereby incorporated by reference in its entirety to the maximum extent allowable by law.

### TECHNICAL FIELD

The present disclosure generally concerns the field of electronic circuits and, more particularly, an optical sensor formed inside and on top of a semiconductor substrate.

### BACKGROUND

An optical sensor generally comprises a plurality of pixels each comprising a photodetector capable of generating an electric signal representative of the intensity of a light radiation that it receives.

So-called multispectral optical sensors, comprising a plurality of pixel types respectively comprising different optical filters in order to measure radiation intensities in different wavelength ranges are more particularly considered here. The present application however also concerns so-called monochromatic sensors, where the different pixels measure intensities of a radiation received in a same wavelength range.

It would be desirable to at least partly improve certain aspects of known optical sensors.

### SUMMARY

An embodiment provides an optical sensor comprising one or a plurality of pixels, each comprising a photodetector and a telecentric system topping the photodetector. Each telecentric system comprises: an opaque layer comprising one or a plurality of openings facing the photodetector; and a microlens facing each opening and arranged between the opaque layer and the photodetector.

According to an embodiment, each pixel comprises an optical filter between the microlenses and the photodetector.

According to an embodiment, the optical filter comprises an interference filter, a diffraction grating-based filter, or a metasurface-based filter.

According to an embodiment, the microlenses have a diameter greater than the diameter of the openings.

According to an embodiment, each microlens comprises at least one planar surface.

According to an embodiment, the planar surfaces of the microlenses are coplanar.

According to an embodiment, the microlenses are laterally separated by opaque walls.

According to an embodiment, the telecentric system comprises at least another microlens facing each microlens and positioned between the microlenses and the photodetector.

According to an embodiment, each microlens is a planar lens.

According to an embodiment, each planar lens comprises a plurality of pads made of a first material, having a first optical index, and surrounded with a second material, having a second optical index different from the first index.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIGS. 1A and 1B very schematically illustrate an example of embodiment of an optical sensor;

FIGS. 2A and 2B show a cross-section view and a top view, respectively, partial and simplified, of an example of an optical sensor according to a first embodiment;

FIG. 3 schematically illustrates an alternative embodiment of the optical sensor illustrated in FIG. 2;

FIG. 4 is a partial simplified cross-section view of an example of an optical sensor according to a second embodiment;

FIG. 5 is a partial simplified cross-section view of an example of an optical sensor according to a third embodiment;

FIG. 6 is a partial simplified cross-section view of an example of an optical sensor according to a fourth embodiment; and

FIG. 7 is a perspective view schematically illustrating microlenses of the optical sensor illustrated in FIG. 6.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the forming of the described sensors has not been detailed, the forming of such sensors being within the abilities of those skilled in the art based on the indications of the present description. Further, the applications capable of taking advantage of the described sensors have not been detailed, the described embodiments being compatible with all or most of the usual applications of optical sensors.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms "front", "back", "top", "bottom", "left", "right", etc., or to relative positional qualifiers, such as the terms "above", "below", "upper", "lower", etc., or to qualifiers of orientation, such as "horizontal", "vertical", etc., reference is made to the orientation shown in the figures.

Unless specified otherwise, the expressions "around", "approximately", "substantially" and "in the order of" signify within 10%, and preferably within 5%.

In the following description, unless specified otherwise, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%.

In the following description, "visible light" designates an electromagnetic radiation having a wavelength in the range from 400 nm to 700 nm. In this range, call red light an electromagnetic radiation having a wavelength in the range from 600 nm to 700 nm, blue light an electromagnetic radiation having a wavelength in the range from 400 nm to 500 nm, and green light an electromagnetic radiation having a wavelength in the range from 500 nm to 600 nm. Further call infrared light an electromagnetic radiation having a wavelength in the range from 700 nm to 1 mm.

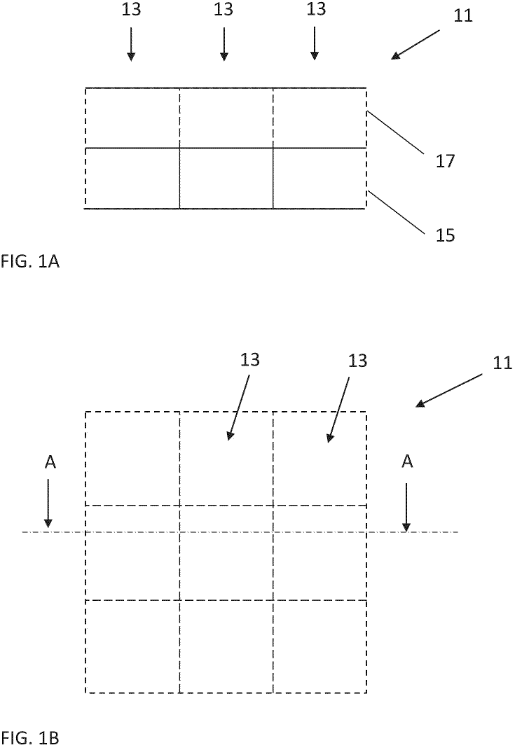

FIGS. 1A and 1B illustrate, in two views, an example of embodiment of an optical sensor 11, where the view of FIG. 1B corresponds to a top view of the sensor, and the view of FIG. 1A corresponds to a cross-section view along the cross-section plane AA of FIG. 1B.

Sensor 11 comprises a plurality of pixels 13, for example, organized in the form of an array of rows and columns. In the example of FIGS. 1A and 1B, sensor 11 comprises nine pixels arranged in an array of three rows and three columns. The described embodiments are of course not limited to this specific case.

Pixels 13, for example, all have, in top view, the same shape and the same dimensions, to within manufacturing dispersions. In the example shown in FIGS. 1A and 1B, pixels 13 have, in top view, a substantially square shape. In top view, the maximum dimension of a pixel 13 is, for example, in the range from 10 µm to 500 µm. The described embodiments are not limited to these specific examples of shape and of dimensions.

Sensor 11 is, for example, an ambient luminosity sensor, comprising a plurality of pixels 13 adapted to respectively measuring the intensity of the ambient light in different wavelength ranges.

Each pixel 13 comprises a photodetector 15 and an optical filter 17 coating a surface of exposure to light of photodetector 15 (upper surface in the orientation of the view shown in FIG. 1A).

Photodetectors 15 are, for example, configured for sensing all or part of a light radiation illuminating sensor 11. As an example, photodetectors 15 are configured for detecting all the visible radiation and/or the infrared radiation. As an example, the photodetectors 15 of a same sensor 11 are all identical, to within manufacturing differences. Photodetectors 15 are, for example, monolithically integrated inside and on top of a same semiconductor substrate, for example a silicon substrate. As an example, each photodetector 15 comprises a photosensitive semiconductor area integrated in the semiconductor substrate. Photodetectors 15 are, for example, photodiodes.

Filters 17, for example, comprise interference filters each corresponding to a multilayer stack having its materials and thicknesses selected to control the wavelength of the radiation crossing it. As a variant, filters 17 may be filters based on diffraction gratings, metasurfaces, or any other type of adapted filters. The filters 17 of pixels 13 different from sensor 11, for example, have different responses. More particularly, the filters 17 of different pixels 13, for example, give way to radiations in different wavelength ranges, so that the different pixels 13 measure radiations in different wavelength ranges.

As an example, sensor 11 comprises: one or a plurality of first pixels 13 called blue pixels, each comprising a first filter 17 called blue filter, configured for mainly giving way to blue light; one or a plurality of second pixels 13 called red pixels, each comprising a second filter 17, called red filter, configured for mainly giving way to red light; and one or a plurality of pixels 13 called green pixels, each comprising a third filter 17, called green filter, configured for mainly giving way to green light.

As an example, sensor 11 may, in addition to the blue, red, and green pixels, comprise: one or a plurality of fourth pixels 13, called infrared pixels, each comprising a fourth filter 17, called infrared filter, configured for mainly giving way to infrared light; and/or one or a plurality of fifth pixels 13, called white pixels, each comprising a fifth pixel 17, called white filter, configured for substantially giving way to all the visible light and to block infrared light.

As a variant, other types of filters 17 configured for giving way to other wavelength ranges different from those listed hereabove may be provided, to obtain signals representative of different wavelength ranges of the light spectrum received by sensor 11.

As an example, in infrared pixels, filter 17 is a bandpass interference filter only giving way to infrared radiation.

In red, green, and blue pixels, filter 17, for example, comprises a bandgap interference filter filtering the infrared radiation, topped with a colored resin filter mainly giving way to a red, respectively green, respectively blue, portion of the visible radiation.

In white pixels, filter 17, for example, comprises a bandgap interference filter filtering the infrared radiation.

The bandgap interference filter is, for example, identical (to within manufacturing dispersions) in red, green, blue, and white pixels. As an example, this filter continuously extends above the photodetectors 15 of the red, green, blue, and white pixels of sensor 11. This filter is however interrupted in front of the infrared filters.

As a variant, in red, green, and blue pixels, filter 17 comprises a specific interference filter mainly giving way to a red, respectively green, respectively blue portion of the visible radiation. In this case, the infrared bandgap interference filter may be omitted in red, green, and blue pixels.

Sensor 11 is, for example, an ambient light sensor (ALS), or a hyperspectral sensor. In such a sensor, it is not desired to obtain an image of a scene, but only a representation of the spectrum of the ambient light.

Conversely to an image sensor, such a sensor is generally not topped with an external optical system for focusing the received light. Indeed, such an external optical system is generally expensive and bulky and is considered undesirable in most usual applications of ambient luminosity sensors.

In practice, the received radiations originate from different sources of the sensor environment, and thus each arrive with different angles of incidence at the sensor surface. It is then desired to detect all the received light radiations, independently from the angle of incidence of these radiations on the sensor surface.

A problem which is posed is that interference filters or, more generally, filters based on diffractive phenomena (diffraction networks, metasurfaces, etc.) are sensitive to the angle of incidence of the light radiations which cross them. In other words, the bandwidth or the bandgap of the sensor filters 17 varies according to the angle of incidence of the received rays. This results in inaccuracies on the representation of the ambient spectrum provided by the sensor.

According to an aspect of an implementation mode, it is provided, to overcome these disadvantages, to top the filter 17 of each pixel 13 with a telecentric system. In each pixel 13, the telecentric system of the pixel has the function of deviating the radiations received by the pixel so that the latter reach the surface of filter 17 with a controlled angle of incidence. In particular, the telecentric system enables to symmetrize the light cone reaching the pixel filter 17, and to decrease the angles of incidence of the rays reaching filter 17. Thus, the sensor response is less sensitive to variations of the characteristics and/or orientations of the ambient light sources.

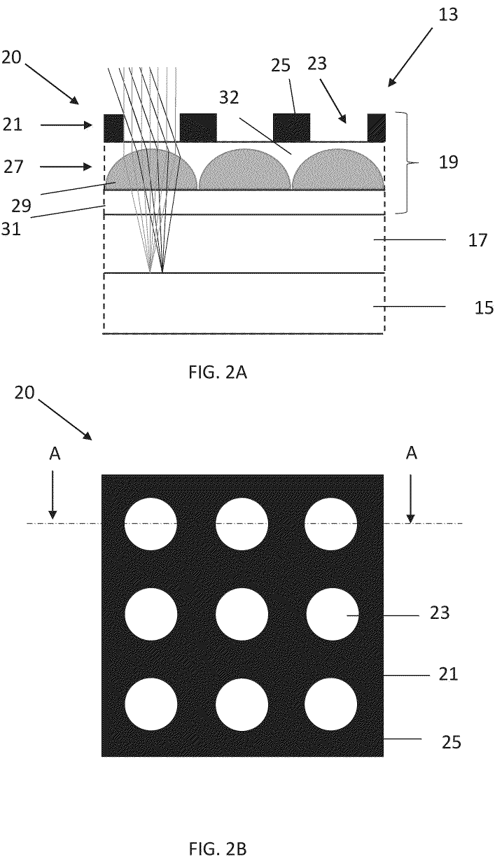

FIGS. 2A and 2B illustrate an example of an optical sensor 20 according to a first embodiment. FIG. 2A comprises a cross-section view and FIG. 2B comprises a top view of sensor 20, the view of FIG. 2A being a cross-section along the plane AA of the view shown in FIG. 2B.

The sensor 20 of FIGS. 2A and 2B comprises the same elements as the sensor 11 of FIGS. 1A and 1B, arranged substantially in the same way, and differs from the sensor 11 of FIGS. 1A and 1B mainly in that, in sensor 20, each pixel 13 comprises, in addition to photodetector 15 and optical filter 17, a telecentric system 19 topping optical filter 17. In other words, sensor 20 comprises a plurality of telecentric systems 19 (one per pixel) respectively topping the optical filters 17 of the different pixels 13. Telecentric systems 19 are monolithically integrated at the scale of the pixels 13 of sensor 20, so that the general bulk of the system remains very limited.

In FIGS. 2A and 2B, for simplification, only one pixel 13 of optical sensor 20 has been shown.

In each pixel 13, telecentric system 19 comprises a layer 21 opaque to light radiations, for example, visible and/or infrared, received by sensor 20. Layer 21 comprises at least one through opening 23 facing optical filter 17 and the photodetector 15 of pixel 13. The portions of layer 21 delimiting opening(s) 23 form walls 25 opaque to said radiation, defining a diaphragm. Telecentric system 19 further comprises a layer 27 of at least one lens 29. In the example of FIGS. 2A and 2B, layer 27 is located between layer 21 and optical filter 17.

In the example of FIGS. 2A and 2B, layer 21 comprises a plurality of openings 23 arranged in a network or in an array. In the example shown in FIGS. 2A and 2B, layer 21 comprises, for each pixel 13, an array of 3x3 openings 23.

Openings 23, for example, have, in top view, a circular shape (the term characteristic dimension of an opening 23 defines the diameter of opening 23 in top view). Openings 23 may as a variant have a shape different from a circle, for example, a hexagonal shape, an octagonal shape, or a square shape (the term characteristic dimension of an opening 23 then defines the diameter the circle inscribed within opening 23 in top view).

Openings 23, for example, have a characteristic dimension in the range from 1 µm to 200 µm, for example, determined according to the dimensions of photodetectors 15, to the number of openings 23 facing each photodetector, and to the incidence cone which is desired to be obtained on the photodetector.

Walls 25 are, for example, opaque to the wavelengths detected by photodetectors 15, here the visible and/or infrared wavelengths. Walls 25 are, for example, made of an opaque resin or of metal, for example, of tungsten.

Walls 25 have a thickness that may depend on the material of layer 21. As an example, if walls 25 are made of resin, they may have a thickness in the range from 500 nm to 1 µm, and if walls 25 are made of metal, they may have a thickness in the order of 100 nm.

In the example of FIGS. 2A and 2B, layer 27 comprises a plurality of microlenses 29. Microlenses 29 are, for example, of micrometer-range size. Microlenses 29 are, for example, plano-convex, they thus each have a planar surface and a bulged non-planar surface. Microlenses 29, for example, rest on a support layer 31 of telecentric system 19, itself resting on the upper surface of filter 17. More particularly, the planar surfaces of microlenses 27 rest on the upper surface of layer 31 and are in contact with layer 31, all the planar surfaces of microlenses 29 are thus coplanar. Support layer 31 is made of a material transparent to the wavelengths detected by the underlying photodetectors 15, for example a silicon oxide or transparent resin.

Microlenses 29, and more particularly the bulged surfaces of microlenses 29, are, for example, topped with a planarizing layer 32. According to an embodiment, layer 32 is a layer having its lower surface following the shape of microlenses 29 and having its upper surface substantially planar. Layer 21 is, for example, located on top of and in contact with the upper surface of layer 32. Layer 32 is made of a material transparent to the wavelengths detected by the underlying photodetectors 15. As an example, layer 32 is made of a material having an optical index (or refraction index) lower than the optical index of the material of microlenses 29. As an example, the material of layer 32 is a resin or an oxide.

In the example shown in FIGS. 2A and 2B, the number of openings 23 is equal to the number of microlenses 29 in each pixel 13. In other words, layer 27 comprises one microlens 29 per opening 23, each microlens 29 being arranged in front of the corresponding opening 23. The array of microlenses 29 preferably has the same arrangement as the array of openings 23 in a matrix of rows and columns. As an example, the optical axis of each microlens 29 runs through the corresponding opening 23, and is preferably aligned with the center of the overlying opening 23. Each microlens 29 is preferably located in front of a single opening 23 and each opening 23 is preferably located vertically in line with a single microlens 29.

Microlenses 29 are, for example, made of an organic resin or of a nitride, for example a silicon nitride. Microlenses 29 are preferably transparent in the wavelength range detected by photodetectors 15. Microlenses 29 are more preferably transparent in the visible and/or infrared range.

As an example, the layer 27 of microlenses 29 and the opaque layer 21 each continuously extend over substantially the entire surface of sensor 20. Further, in the example of FIGS. 2A and 2B, support layer 31 and planarizing layer 32 each continuously extend over substantially the entire surface of sensor 20.

As an example, the microlenses 29 of sensor 20 are all identical (to within manufacturing dispersions). As a variant, microlenses 29 may have different dimensions within a pixel 13 and/or between different pixels 13 of sensor 20.

As an example, openings 23 have a characteristic dimension smaller than the diameter (in top view) of microlenses 29.

As an example, the upper surface of layer 21 is located in the object focal plane of microlenses 29 to obtain a telecentric effect. The upper surface of photodetectors 15 is, for example, but not necessarily, located in the image focal plane of microlenses 29.

Telecentric system 19 enables, by the presence of opening layer 23, to filter the radiations arriving with an angle of incidence greater than a defined angle of incidence.

Telecentric system 19 further enables to focus, in a cone converging at the surface of a photodetector 15, the radiations arriving with an angle of incidence smaller than or equal to the defined angle of incidence. Telecentric system 19 particularly enables to symmetrize the light cone reaching the pixel filter 17, and to decrease the angles of incidence of the rays arriving on filter 17. In practice, the width of openings 23 defines the cone angle. The smaller openings 23, the smaller the cone angle.

Thus, an advantage of the embodiment illustrated in FIGS. 2A and 2B is that it enables to limit the angle of incidence of the radiations arriving at the surface of filters 17, and thus to limit artifacts linked to the sensitivity of filter 17 to the angle of incidence.

In the above-described example, each pixel comprises a telecentric system 19 comprising a plurality of telecentric sub-systems arranged in a same plane, each telecentric sub-system comprising a stack of a diaphragm defined by an opening 23, and of a microlens 29. An advantage of this configuration is that it enables to gain compactness for the system. Indeed, the thickness of the telecentric system may be decreased with respect to a telecentric system comprising a single diaphragm and a single microlens, covering the entire surface of the photodetector, particularly for photodetectors of large dimensions. The described embodiments are however not limited to this specific case. As a variant, each pixel may comprise a single telecentric sub-system, that is, a single opening 23 and a single microlens 29.

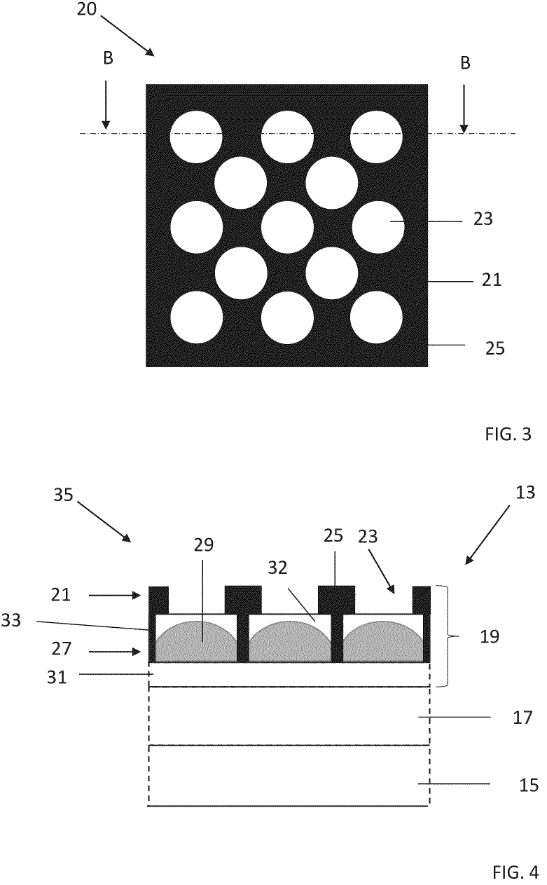

FIG. 3 schematically illustrates an alternative embodiment of the optical sensor 20 illustrated in FIGS. 2A and 2B. More particularly, FIG. 3 is a top view of a pixel, similar to the view shown in FIG. 2B, but illustrating another example of arrangement of the telecentric sub-systems of the pixel. In the example of FIG. 3, the telecentric sub-systems are arranged in quincunx.

FIG. 4 is a cross-section view of an example of an optical sensor 35 according to a second embodiment.

More particularly, FIG. 4 illustrates an optical sensor 35 similar to the optical sensor 20 illustrated in FIGS. 2A and 2B, with the difference that each microlens 29 of the sensor 35 illustrated in FIG. 4 is laterally separated from the neighboring microlenses 29 by walls 33.

Walls 33 are made of a material opaque to the wavelengths detected by the underlying photodetectors 15, for example the visible and/or infrared wavelengths in the considered example. Walls 33 are, for example, made of the same material as walls 25. As an example, walls 33 are made of opaque resin or of metal, for example comprising tungsten.

Walls 33 are, for example, formed by etching of trenches in layers 27 and 32, and then filling of the trenches with an opaque material.

In this example, walls 33 extend between the microlenses 29 of layer 27 all along the height of layers 27 and 32 between the upper surface of layer 31 and the lower surface of walls 25. Walls 33 are, for example, located in front of walls 25 but have a width (horizontal dimension in the orientation of FIG. 4) smaller than that of walls 25.

Walls 33 particularly enable to avoid optical crosstalk between two neighboring pixels 13 and/or to improve the efficiency of the telecentric system.

FIG. 5 is a cross-section view illustrating an example of an optical sensor 36 according to a third embodiment.

More particularly, FIG. 5 illustrates an optical sensor 36 similar to the optical sensor 20 illustrated in FIGS. 2A and 2B, with the difference that the telecentric system 19 of the sensor 36 of FIG. 5 comprises a second layer 37 of microlenses 39 between the layer 27 of microlenses 29 and optical filters 17. More particularly, in this example, the layer 37 of microlenses 39 is arranged between the layer 27 of microlenses 29 and the support layer 31 coating optical filters 17.

Microlenses 39 are, for example, organized according to the same array network as microlenses 29, each of microlenses 39 being associated with a microlens 29 so that the optical axis of each microlens 39 is confounded with the optical axis of a corresponding microlens 29.

As an example, microlenses 39 are made of the same material as microlenses 29.

In the example illustrated in FIG. 5, microlenses 39 have the same geometry as microlenses 29. Microlenses 29 and 39 thus have the same shape, the same diameter, the same radius of curvature, and the same focal distance.

As a variant, microlenses 39 have a geometry different from that of microlenses 29. Microlenses 39 then have a diameter, a radius of curvature, and/or a focal distance respectively different from the diameter, the radius of curvature, and/or the focal distance of microlenses 29.

Like microlenses 29, microlenses 39 may be topped with a planarizing layer 41 similar or identical to layer 32. According to an embodiment, layer 41 has a lower surface following the shape of microlenses 39 and a substantially planar upper surface.

In the example shown in FIG. 5, layer 27 is located on top of and in contact with the upper surface of layer 41.

An advantage of the embodiment illustrated in FIG. 5 is that it enables to further rectify the received radiations, to symmetrized the light cone, and thus to improve the efficiency of the telecentric system.

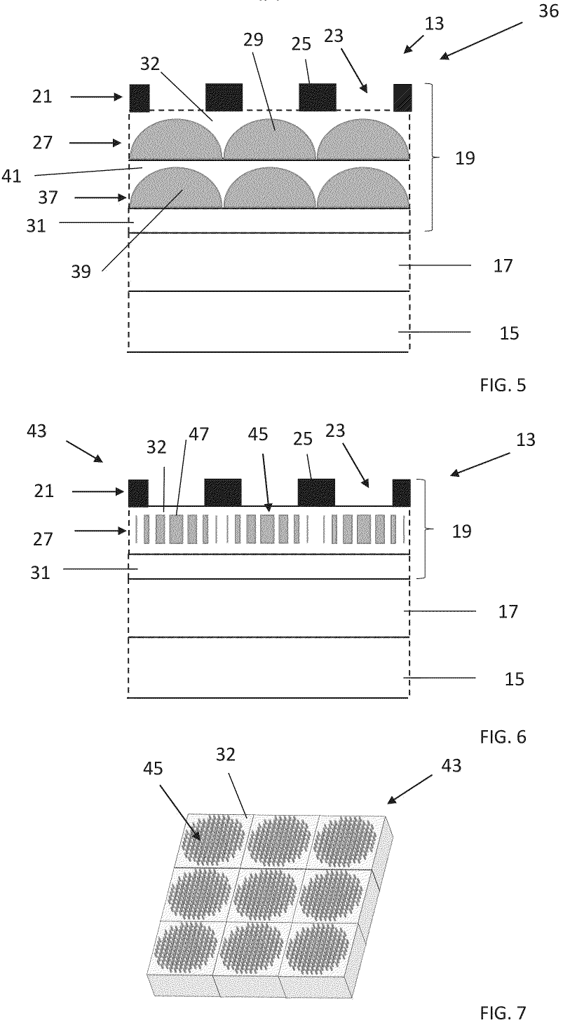

FIG. 6 is a cross-section view illustrating an example of an optical sensor according to a fourth embodiment.

FIG. 7 is a perspective view of a portion of the optical sensor illustrated in FIG. 6.

The optical sensor 43 of FIG. 6 is similar to the optical sensor 20 illustrated in FIGS. 2A and 2B with the difference that, in the telecentric system 19 of the sensor 43 of FIG. 6, each lens 29 of layer 27 of microlenses is replaced with a planar microlens or metalens 45.

FIG. 7 is a perspective view of the layer 27 of microlens 45.

Each microlens 45 comprises a plurality of pads 47. Pads 47, for example, correspond to cylindrical structures. Pads 47, for example, all have the same thickness (vertical dimension in the orientation of FIG. 6). Pads 47 of a same microlens 45 may, however, have different diameters. As an example, the diameter of pads 47 increases as the distance to the center of metalens 45 decreases. It will be within the abilities of those skilled in the art to select the arrangement and the sizing of pads 47 to obtained the desired optical function.

Pads 47 are, for example, made of a material transparent to the wavelengths detected by the underlying photodetector 15, for example at visible and/or infrared wavelengths, in the considered example. As an example, pads 47 are made of polysilicon or of silicon nitride. Pads 47 are laterally separated from one another by a transparent material having an optical index different from that of pads 47, for example, a material having an optical index smaller than that of pads 47, for example a silicon oxide.

In the example shown in FIGS. 6 and 7, the pads 47 of metalenses 45 are embedded in layer 32.

An advantage of the embodiment illustrated in FIGS. 6 and 7 is that it enables to adjust at best the telecentric system for the targeted application by controlling the diameter and the spacing between each of the pads 47 of the metalenses.

Another advantage of the embodiment illustrated in FIGS. 6 and 7 is that it enables to gain compactness for the telecentric system and accordingly for the image sensor. Indeed, metalenses 45 may, for a constant thickness, have relatively complex optical functions, for example, optical functions equivalent to those of a stack of a plurality of curved microlenses, for example, of the type described in relation with FIG. 5.

Various embodiments and variants have been described. Those skilled in the art will understand that certain features of these various embodiments and variants may be combined, and other variants will occur to those skilled in the art. In particular, the embodiments illustrated in FIGS. 4 and 5 may be combined and the embodiments illustrated in FIGS. 4 and 6 may also be combined.

Further, the described embodiments are not limited to the examples of dimensions and of materials mentioned hereabove.

Further, the above-described embodiments are not limited to the specific example of application of ambient light sensors described hereabove, but may be adapted to any optical sensor capable of taking advantage of a control of the angles of incidence of the radiations received by the photodetectors of the sensor pixels. The described embodiments are particularly advantageous for sensors comprising optical interference filters above the photodetectors of the sensor pixels. The described embodiments are however not limited to this specific case. For certain applications, for example, in the case of a monochromatic image sensor, optical filters 17 may be omitted. The described embodiments then particularly enable to symmetrize and to decrease the cone of incidence of the rays arriving on the pixels in order to, for example, uniformize the light everywhere on the sensor.

Finally, the practical implementation of the described embodiments and variations is within the abilities of those skilled in the art based on the functional indications given hereabove.

1. An optical sensor, comprising one or more pixels, wherein each pixel comprises:
a photodetector; and
a telecentric system topping the photodetector;
wherein each telecentric system comprises:
an opaque layer comprising a plurality of openings facing the photodetector; and
a microlens facing each opening and arranged between the opaque layer and the photodetector.

2. The optical sensor according to claim 1, wherein each pixel further comprises an optical filter between the microlenses and the photodetector.

3. The optical filter according to claim 2, wherein the optical filter comprises an interference filter.

4. The optical filter according to claim 2, wherein the optical filter comprises a diffraction grating-based filter.

5. The optical filter according to claim 2, wherein the optical filter comprises a metasurface-based filter.

6. The optical sensor according to claim 1, wherein each microlens has a diameter greater than a diameter of the opening to which the microlens faces.

7. The optical sensor according to claim 1, wherein each microlens comprises a planar surface.

8. The optical sensor according to claim 7, wherein the planar surfaces of the microlenses are coplanar.

9. The optical sensor according to claim 1, wherein the microlenses are laterally separated by opaque walls.

10. The optical sensor according to claim 1, wherein each telecentric system further comprises another microlens facing each microlens and positioned between the microlens and the photodetector.

11. The optical sensor according to claim 10, wherein the microlens and the another microlens facing the microlens have same shapes, same diameters, same radii of curvature, and same focal distances.

12. The optical sensor according to claim 10, wherein the microlens and the another microlens facing the microlens have different shapes, different diameters, different radii of curvature, and different focal distances.

13. The optical sensor according to claim 1, wherein each microlens is a planar lens.

14. The optical sensor according to claim 13, wherein each planar lens comprises a plurality of pads made of a first material having a first optical index, surrounded with a second material having a second optical index different from the first index.

15. The optical sensor according to claim 1, wherein the plurality of openings are arranged in quincunx.

16. A pixel for an optical sensor, comprising:
a photodetector;
a filter layer extending over the photodetector;
a transparent support layer extending over the filter layer;
a plurality of microlenses arranged in an array and supported by said support layer over the photodetector;
an opaque layer extending over the plurality of microlenses, where said opaque layer includes a plurality of openings, wherein each opening in said plurality of openings is aligned with a corresponding microlens of said plurality of microlenses; and
wherein said filter layer provides an optical filter comprising an interference filter formed by a multilayer stack, wherein layer thickness and layer material are selected to control a wavelength of radiation passing through the filter layer.

17. The pixel of claim 16, wherein each microlens has a diameter greater than a diameter of the opening to which the microlens corresponds.

18. The pixel of claim 16, wherein each microlens comprises a planar surface.

19. The pixel of claim 18, wherein the planar surfaces of the microlenses are coplanar.

20. The pixel of claim 16, wherein said opaque layer further extends to form opaque walls positioned between adjacent ones of the microlenses is said plurality of microlenses.

21. The pixel of claim 16, wherein said array arranges said openings in quincunx.
